(19) United States
(12) Patent Application Publication
(10) Pub. No.: US 2018/0123065 A1
(43) Pub. Date: May 3, 2018

(54) ORGANIC ELECTRONIC DEVICE AND SUBSTRATE FOR ORGANIC ELECTRONIC DEVICE

(71) Applicant: Kabushiki Kaisha Kobe Seiko Sho (Kobe Steel, Ltd.), Kobe-shi (JP)

(72) Inventors: Yoko SHIDA, Hyogo (JP); Masao MIZUNO, Hyogo (JP); Yasuo HIRANO, Hyogo (JP); Tatsuhiko IWA, Hyogo (JP); Takeshi WATASE, Hyogo (JP)

(73) Assignee: Kabushiki Kaisha Kobe Seiko Sho (Kobe Steel, Ltd.), Kobe-shi (JP)

(21) Appl. No.: 15/568,534

(22) PCT Filed: May 24, 2016
(86) PCT No.: PCT/JP2016/065321

§ 371 Date: Oct. 23, 2017

(30) Foreign Application Priority Data
May 28, 2015 (JP) 2015-109226

(51) Int. Cl. H01L 51/44; H01L 51/50; F21S 2/00; H01L 51/00

(52) U.S. Cl. CPC H01L 51/44; H01L 51/0097; F21S 2/00; H01L 51/50

(57) ABSTRACT

An organic electronic device provided with an organic electronic element on one surface of a substrate, wherein the substrate has a metal layer and an insulating layer overlaid on at least one face side of the metal layer, and the one face of the substrate does not have an irregularity peak having a K value of equal to or lower than −0.07 as calculated by expression (1). In the expression (1), x represents an irregularity peak position when a line roughness analysis is conducted on a 10 μm square on the one face of the substrate with an interval of 2.45 nm, f(x) represents a surface irregularity height (nm) at x, and dx represents an infinitesimal change in x. K=[f(x+dx)−2f(x)+f(x−dx)]/dx² . . . (1)

### TECHNICAL FIELD

The present invention relates to an organic electronic device and a substrate for an organic electronic device.

### BACKGROUND ART

An organic electronic device in which an organic semiconductor is employed is flexible, enables reduction in thickness, and is power-saving. Therefore, applications of such an organic electronic device to an organic EL (electroluminescence) lighting system, a solar cell, and the like are expected. The organic EL lighting system requires at least a luminescence layer including an organic semiconductor, and is further provided with a charge injection layer, a charge transport layer and the like in order to improve luminescence efficiency. The solar cell includes an electron donor, an electron acceptor, and the like.

Owing to low charge mobility, the organic semiconductor is often used in an extremely thin film-like shape, which is typically formed as a layer having a thickness of several tens of nm to several pm. Accordingly, any irregularities on a substrate (base material), on which the organic semiconductor is to be overlaid, lead to short-circuit of an element, resulting in a low production yield.

In this regard, an organic EL element has been proposed in which, in order to planarize an abnormal projection on a substrate, a resin coating film having a thickness of 0.1 μm to several tens of pm is applied onto a polished glass substrate (see Japanese Unexamined Patent Application, Publication No. 2000-021563). However, sufficient flatness may not be obtained by this technique, since a surface profile of the polished substrate is not specified.

In addition, an insulating substrate for an organic EL element has been proposed, comprising: a metal plate or a metal foil as a base material; and an insulating layer constituted of an organic resin, having a thickness of 1 to 40 μm, surface roughness Ra≤0.5 μm and Rmax≤1.5 μm, and being formed on a surface of the base material (see Japanese Unexamined Patent Application, Publication No. 2002-025763). However, a verification by the present inventors revealed that such an element may short-circuit even when the surface roughness is less than or equal to a predetermined value, and that specifying the surface roughness is not enough for ensuring flatness of the substrate.

### PRIOR ART DOCUMENTS

### Patent Documents

Patent Document 1: Japanese Unexamined Patent Application, Publication No. 2000-021563

Patent Document 2: Japanese Unexamined Patent Application, Publication No. 2002-025763

### SUMMARY OF THE INVENTION

### Problems to be Solved by the Invention

The present invention was made in view of the foregoing circumstances, and an object of the present invention is to provide an organic electronic device and a substrate for an organic electronic device that are superior in production yield due to inhibition of occurrence of short-circuit of the element.

### Means for Solving the Problems

The present inventors have thoroughly investigated and consequently found that flatness of the substrate can be ensured by specifying a shape of irregularities on a surface of the substrate with specific conditions.

According to an aspect of the invention made for solving the aforementioned problems, an organic electronic device comprises a substrate and an organic electronic element overlaid on one face of the substrate, wherein: the substrate comprises a metal layer and an insulating layer overlaid on at least one face side of the metal layer; and the one face of the substrate does not have an irregularity peak having a K value of less than or equal to −0.07 as calculated by the following equation (1):

K=[f(x+dx)−2f(x)+f(x−dx)]/dx² (1)

wherein in the equation (1): x represents an irregularity peak position when a line roughness analysis is conducted on a 10 μm square on the one face of the substrate with an interval of 2.45 nm; f(x) represents a surface irregularity height (nm) at x; and dx represents an infinitesimal change in x.

In the organic electronic device of the present embodiment, due to the absence of an irregularity peak having the K value of less than or equal to a predetermined value, on a face of the substrate on which the organic electronic element is to be overlaid (hereinafter, may be also referred to as “organic electronic element-laminated face”), no precipitous projection exists on the organic electronic element-laminated face. Accordingly, flatness of the face is ensured, and consequently occurrence of short-circuit of the element is inhibited. As a result, the organic electronic device is superior in production yield.

The insulating layer preferably contains a synthetic resin as a principal component. Due to using a synthetic resin as a principal component of the insulating layer, easy formation of a highly insulating layer is enabled. It is to be noted that the term “principal component” as referred to means a component of which content is the greatest, for example a component of which content is greater than or equal to 50% by mass.

The insulating layer preferably contains a pigment. Due to adding a pigment to the insulating layer, acceleration of planarization of the surface profile is enabled through inhibition of contraction of the resin, etc.

The pigment is preferably an inorganic pigment, a mean particle diameter of the pigment is preferably less than or equal to 300 nm, and a content of the pigment in the insulating layer is preferably less than or equal to 50% by mass. Adding the organic pigment having a mean particle diameter of less than or equal to 300 nm in an amount of less than or equal to 50% by mass enables inhibition of generation of a projection on a surface of the insulating layer, and further acceleration of planarization of the surface profile. It is to be noted that the term “mean particle diameter” as referred to means a particle diameter at 50% cumulative volume from the smallest particle (D50), calculated based on measurement results of a particle size distribution of particles by using a general particle size distribution analyzer. Such a particle size distribution may be measured based on intensity patterns of diffraction and scattering as a result of irradiating the particles with light. The particle size distribution analyzer is exemplified by Microtrack 9220 FRA and Microtrack HRA available from Nikkiso Co., Ltd., and the like.

The synthetic resin is preferably a thermosetting resin. Using a thermosetting resin as a principal component of the insulating layer enables easier formation of the insulating layer.

The synthetic resin is preferably a polyester, and the insulating layer preferably contains a thermosetting agent. Using a polyester as a principal component of the insulating layer and using a thermosetting agent in combination enable formation of the insulating layer at a lower cost.

The metal layer preferably includes iron, titanium, or an alloy thereof as a principal component. Selecting a principal component of the metal layer from these metals enables easy and reliable formation of a substrate superior in strength and durability.

As described above, the organic electronic device of the present embodiment is superior in production yield, and may be therefore suitably used for an organic EL lighting system or an organic solar cell.

According to another aspect of the invention made for solving the aforementioned problems, a substrate for an organic electronic device comprises the substrate and an organic electronic element overlaid on one face of the substrate comprising a metal layer and an insulating layer overlaid on at least one face side of the metal layer, wherein the one face of the substrate does not have an irregularity peak having a K value of less than or equal to −0.07 as calculated by the above equation (1).

The substrate for an organic electronic device of the present embodiment is superior in production yield as described above.

### Effects of the Invention

As explained in the foregoing, the organic electronic device and the substrate for an organic electronic device according to the embodiments of the present invention are superior in production yield, due to inhibition of occurrence of short-circuit of the element.

### BRIEF DESCRIPTION OF THE DRAWINGS

FIG. 1A is a schematic cross sectional view showing an example of the organic electronic device according to an embodiment of the present invention;

FIG. 1B is a schematic cross sectional view showing another example of the organic electronic device according to the embodiment of the present invention;

FIG. 1C is a schematic cross sectional view showing still another example of the organic electronic device according to the embodiment of the present invention; and

FIG. 2 is a schematic plan view showing an organic electronic device formed in Examples.

### DESCRIPTION OF EMBODIMENTS

Embodiments of the organic electronic device and the substrate for an organic electronic device will be described in detail with appropriate reference to the drawings.

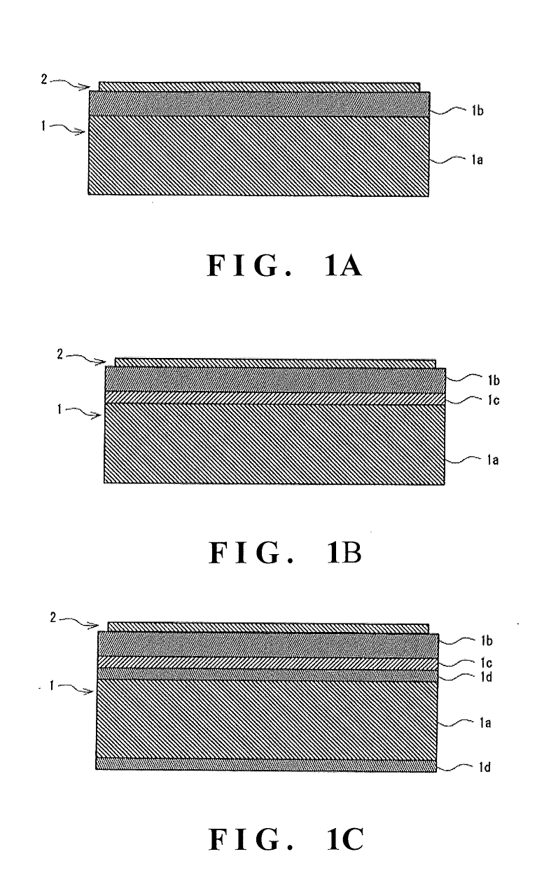

The organic electronic devices shown in FIGS. 1A to 1C each include a substrate 1 and an organic electronic element 2 overlaid on one face of the substrate 1.

### Substrate

The substrate 1 is the substrate for an organic electronic device according to an embodiment of the present invention, and includes a metal layer 1a and an insulating layer 1b overlaid on at least one face (organic electronic element-laminated face) side of the metal layer 1a.

### (Metal Layer)

The metal layer 1a contains metal as a principal component. The metal is exemplified by iron, titanium, or an alloy thereof. Specific examples of the metal layer 1a include metal sheets such as: a cold-rolled steel plate; a hot-dip galvanized steel sheet (GI); an alloyed hot-dip Zn—Fe plated steel sheet (GA); an alloyed hot-dip Zn-5% Al plated steel sheet (GF); an electrogalvanized steel sheet (EG); an Zn—Ni electroplated steel plate; a steel sheet; a titanium sheet; and a Galvalume sheet.

The aforementioned steel plates preferably have been subjected to a non-chromate treatment; however, steel plates having been subjected to a chromate treatment or no treatment may also be used. Alternatively, the steel plates may have been subjected to a chemical conversion treatment with a phosphoric acid-based compound. In particular, metal sheets plated using zinc preferably have been subjected to a chemical conversion treatment by an acidic aqueous solution containing colloidal silica and an aluminum phosphate salt compound. When the acidic aqueous solution containing colloidal silica and an aluminum phosphate salt compound is used as a chemical conversion treatment solution, the acidic aqueous solution etches a surface of a zinc-containing plated layer. Simultaneously, a reaction layer 1c constituted mainly of AlPO₄ and/or Al₂(HPO₄)₃, which are hardly soluble in water or an alkaline aqueous solution among aluminum phosphates, is formed on the surface of the zinc-containing plated layer, as shown in FIG. 1B. In other words, the reaction layer 1c is overlaid on the organic electronic element-laminated face side of the metal layer 1a. Then, silica particulates are deposited on and incorporated into the reaction layer 1c, and consequently the aluminum phosphate and the silica particulates are integrated to form a composite. Meanwhile, the reaction layer 1c is tightly formed on the surface of the zinc-containing plated layer having been roughed by the etching, and consequently a bond between the reaction layer 1c and the insulating layer 1b formed thereon becomes tight and firm. Furthermore, adding a water soluble resin such as polyacrylic acid to the acidic aqueous solution enables an even firmer deposition state of the silica particulates in the reaction layer 1c to be obtained.

In addition, a rust-preventive layer 1d may be provided on both faces of the metal layer 1a as shown in FIG. 1C. When the rust-preventive layer 1d is provided, durability of the substrate 1 is improved and long-term use is achieved. In a case of providing the rust-preventive layer 1d on the organic electronic element-laminated face of the metal layer 1a, the reaction layer 1c is overlaid on an organic electronic element-laminated face of the rust-preventive layer 1d. It is to be noted that the rust-preventive layer 1d may be overlaid only on one face, in particular only on the organic electronic element-laminated face, of the metal layer 1a.

The average thickness of the metal layer 1a is not particularly limited, and may be greater than or equal to 0.3 mm and less than or equal to 2.0 mm.

### (Insulating Layer)

The insulating layer 1b is a layer having an insulation property, and preferably contains the synthetic resin as a principal component. As the synthetic resin, a thermosetting resin, a thermoplastic resin, a photocurable resin, and the like may be used. Of these, a thermosetting resin, or a combination of other resin (e.g., a thermoplastic resin) with a thermosetting agent is preferably used. The insulating layer 1b may also contain, in addition to the synthetic resin, a pigment and the like.

The thermosetting resin is not particularly limited, and exemplified by a phenol resin, an epoxy resin, a urea resin, a melamine resin, a diallyl phthalate resin, and the like. As a principal component of the insulating layer 1b, a polyester is preferred. In the case of using a polyester, the insulating layer 1b may be formed from a resin composition having a thermosetting property by adding a thermosetting agent (described later) to the insulating layer 1b.

The polyester is obtained through a condensation reaction between a polybasic acid such as a dibasic acid, and a polyhydric alcohol. The polybasic acid as a material for the polyester is exemplified by: α,β-unsaturated dibasic acids such as maleic acid, maleic anhydride, fumaric acid, itaconic acid and itaconic anhydride; saturated dibasic acids such as phthalic acid, phthalic anhydride, halogenated phthalic anhydride, isophthalic acid, terephthalic acid, tetrahydrophthalic acid, tetrahydrophthalic anhydride, hexahydrophthalic acid, hexahydroisophthalic acid, hexahydroterephthalic acid, cyclopentadiene-maleic anhydride adduct, succinic acid, malonic acid, glutaric acid, adipic acid, sebacic acid, 1,10-decanedicarboxylic acid, 2,6-naphthalene dicarboxylic acid, 2,7-naphthalene dicarboxylic acid, 2,3-naphthalene dicarboxylic acid, 2,3-naphthalene dicarboxylic anhydride, 4,4′-biphenyl dicarboxylic acid, or dialkyl esters; and the like. However, the polybasic acid is not particularly limited. These polybasic acids may be used alone or in mixture of two or more types thereof as appropriate.

The polyhydric alcohol as a material for the polyester is exemplified by: ethylene glycols such as ethylene glycol, diethylene glycol and polyethylene glycol; propylene glycols such as propylene glycol, dipropylene glycol and polypropylene glycol; 2-methyl-1,3-propanediol; 1,3-butanediol; an adduct of bisphenol A and propylene oxide or ethylene oxide; glycerin; trimethylol propane; 1,3-propanediol, 1,2-cyclohexane glycol; 1,3-cyclohexane glycol; 1,4-cyclohexane glycol; paraxylene glycol; bicyclohexyl-4,4′-diol; 2,6-decalin glycol; tris(2-hydroxyethyl) isocyanurate; and the like. However, the polyhydric alcohol is not particularly limited. Alternatively, an amino alcohol such as ethanol amine may be used. These polyhydric alcohols may be used alone or as a mixture of two or more types thereof as appropriate.

In addition, the polyester may have been modified by an epoxy resin, diisocyanate, dicyclopentadiene, etc. as needed.

As the resin used for the insulating layer 1b, various commercially available products may be suitably used. In particular, the commercially available product of the polyester may be exemplified by Vylon (registered trademark) 23CS, Vylon (registered trademark) 29CS, Vylon (registered trademark) 29XS, Vylon (registered trademark) 20SS, Vylon (registered trademark) 29SS (available from Toyobo Co., Ltd.), and the like.

Although the insulating layer 1b is premised to be not soluble in an organic solvent, a solvent used during molding may infiltrate into the layer, leading to an alteration such as swelling. For inhibition of such an alteration, adding a predetermined amount of the thermosetting agent even in the case of using the thermosetting resin as the synthetic resin, thereby increasing a degree of curing (crosslinking density) of the insulating layer 1b, would be effective.

The thermosetting agent is not particularly limited; however, thermosetting agents that are highly compatible with the polyester and/or the thermosetting resin, capable of crosslinking the polyester and/or the thermosetting resin, and superior in solution stability are preferred. Such a thermosetting agent is exemplified by: isocyanate thermosetting agents such as Millionate (registered trademark) N, Coronate (registered trademark) T, Coronate (registered trademark) HL, Coronate (registered trademark) 2030, Suprasec 3340, Dultosec 1350, Dultosec 2170 and Dultosec 2280 (available from Nippon Polyurethane Industry Co., Ltd.); melamine resin thermosetting agents such as Nikarac (registered trademark) MS-11, Nikarac (registered trademark) MS21 (available from Sanwa Chemical Co., Ltd), Super Beckamine (registered trademark) L-105-60, Super Beckamine (registered trademark) J-820-60 (available from DIC Corporation); epoxy thermosetting agents such as hardener HY951, hardener HY957 (available from BASF SE), Sumicure DTA and Sumicure TTA (available from Sumitomo Chemical Co., Ltd.); and the like.

The lower limit of a content of the synthetic resin in the insulating layer 1b is preferably 26.5% by mass and more preferably 36.0% by mass. Meanwhile, the upper limit of the content of the synthetic resin is preferably 80.0% by mass and more preferably 56.3% by mass. When the content of the synthetic resin falls within the aforementioned range, formation of an insulating layer suited for the substrate 1 is enabled. It is to be noted that the content of the synthetic resin as referred to means a proportion of a mass of the synthetic resin to a total mass of the solid content (synthetic resin, thermosetting agent, pigment, etc.) in the insulating layer 1b. The same definition applies to contents of the thermosetting agent and the like described later.

The lower limit of a content of the thermosetting agent in the insulating layer 1b is preferably 10.0% by mass and more preferably 20.0% by mass. Meanwhile, the upper limit of the content of the thermosetting agent is preferably 50.0% by mass. When the content of the thermosetting agent falls within the aforementioned range, easy and reliable formation of the insulating layer 1b is enabled.

The lower limit of a mass ratio of the thermosetting agent to the synthetic resin in the insulating layer 1b is preferably 0.3, more preferably 0.4, and still more preferably 0.65. Meanwhile, the upper limit of the mass ratio of the thermosetting agent is preferably 1.0.

In the case in which the insulating layer 1b is constituted of the polyester and/or the thermosetting resin, volumetric shrinkage may be caused during curing, and the surface profile may be largely undulated or may have irregularities, due to a volatilized gas component of the solvent. In this regard, by blending the pigment into the insulating layer 1b, inhibition of shrinkage of the synthetic resin and acceleration of elimination of the solvent gas are enabled, and consequently planarization of the surface profile is achieved. On the other hand, addition of the pigment increases surface roughness, leading to formation of a large number of projections on the surface. Therefore, it is necessary to adjust the particle diameter and an amount of addition of the pigment.

Specifically, the mean particle diameter of the pigment is preferably greater than or equal to 100 nm and less than or equal to 300 nm. Meanwhile, the content of the pigment in the insulating layer 1b is preferably greater than or equal to 30% by mass and less than or equal to 50% by mass.

The pigment may be, for example, a white pigment exemplified by inorganic pigments such as titanium oxide, calcium carbonate, zinc oxide, barium sulfate, lithopone and lead white, or a black pigment exemplified by: organic pigments such as aniline black and nigrosine; inorganic pigments such as carbon black and iron black; and the like. There are other organic pigments; however, in light of surface profile adjustment, which is the object of the addition of the pigment, the inorganic pigment is preferably used.

As the pigment, a commercially available product may be used as long as the mean particle diameter falls within the preferred range specified above. The commercially available product is exemplified by JR-806 (mean particle diameter: 0.25 μm) (available from Tayca Corporation), Tipaque (registered trademark) CR-50 (mean particle diameter: 0.25 μm) and Tipaque (registered trademark) R930 (mean particle diameter: 0.25 μm) (available from Ishihara Sangyo Kaisha, Ltd.), and the like.

In order to inhibit segregation of the pigment, a pigment dispersant may be added to the insulating layer 1b. As the pigment dispersant, a water soluble acrylic resin, a water soluble styrene acrylic resin, a nonionic surfactant, and a combination thereof are preferred.

The lower limit of an average thickness of the insulating layer 1b is preferably 5 μm and more preferably 10 μm. Meanwhile, the upper limit of the average thickness of the insulating layer 1b is preferably 30 μm and more preferably 20 μm. When the average thickness of the insulating layer 1b is less than the lower limit, the insulation property of the substrate 1 may be insufficient. To the contrary, when the average thickness of the insulating layer 1b is greater than the upper limit, the flexibility of the substrate 1 may be insufficient.

Resistivity of the insulating layer 1b is preferably greater than or equal to 10¹⁰ Ωcm. It is to be noted that the term “resistivity” as referred to means a value measured pursuant to JIS-K-7194 (1994).

### (K Value)

In the organic electronic device, the one face of the substrate does not have an irregularity peak having a K value of less than or equal to −0.07 as calculated by the following equation (1).

K=[f(x+dx)−2f(x)+f(x−dx)]/dx² (1)

In the above equation (1): x represents an irregularity peak position when a line roughness analysis is conducted on a 10 μm square on the one face of the substrate with an interval of 2.45 nm; f(x) represents a surface irregularity height (nm) at x; and dx represents an infinitesimal change in x.

The K value represents a curvature of a projection (irregularity peak) on the surface of the substrate 1, and a greater K value, i.e., a greater curvature, indicates less sharpness of the projection. The present inventors have found that the precipitous projection on the surface of the substrate causes electrolytic concentration to consequently trigger short-circuit of the element, and that getting rid of an irregularity peak having the K value of less than or equal to −0.07, i.e., adjusting the K value on the surface of the substrate to be greater than −0.07, enables elimination of the projection that causes the short-circuit of the element. The K value may be adjusted through, for example, polishing as described later in relation to the production method of the organic electronic device. It is to be noted that dx may be a calculation interval for x, and specifically, may be approximately greater than or equal to 2 nm and less than or equal to 10 nm.

Furthermore, the upper limit of the number of irregularity peaks on the one face of the substrate having the K value of less than or equal to −0.05 is preferably 5, more preferably 3, still more preferably 1, and particularly preferably 0.

### Organic Electronic Element

The organic electronic element 2 may be an organic EL element, a solar cell element, a liquid crystal display element, a thin film transistor, a touchscreen element, an electronic paper element and the like.

The organic EL element is exemplified by an element in which an anode, an organic light-emitting layer, and a cathode are laminated in this order. The organic EL element may also include in the lamination other layers such as an electron injection layer, an electron transport layer and a hole transport layer, as appropriate. As the components constituting the organic EL element, well-known components may be used. As the anode, for example a transparent electrode made of indium tin oxide (ITO) may be used. As the cathode, for example an electrode made of a metal or indium zinc oxide may be used. A principal component of the organic light-emitting layer may be α-NPD.

Due to using the organic EL element as the organic electronic element 2, the organic electronic device is enabled to be suitably used for an organic EL lighting system.

In addition, due to using as the organic electronic element 2 a solar cell element in which an anode, an electron donor, an electron acceptor and a cathode are laminated in this order, for example, the organic electronic device is enabled to be suitably used for an organic solar cell.

### Production Method

The organic electronic device according to the present embodiment can be obtained by a production method comprising, for example, providing the substrate 1, and overlaying the organic electronic device 2 on one face of the substrate 1.

### (Substrate Providing Step)

In this step, the insulating layer 1b is overlaid on the organic electronic element-laminated face side of the metal layer 1a through application of an insulating layer-forming composition and heating to form the substrate 1. The insulating layer-forming composition is preferably in a liquid form. In other words, the insulating layer-forming composition preferably contains a solvent.

The solvent used for the insulating layer-forming composition is not particularly limited as long as each component to be contained in the insulating layer-forming composition can be dissolved or dispersed therein. The solvent is exemplified by: alcohols such as methanol, ethanol, n-propanol, isopropanol, n-butanol, isobutanol and ethylene glycol; ketones such as acetone, methyl ethyl ketone, methyl isobutyl ketone and cyclohexanone; aromatic hydrocarbons such as toluene, benzene, xylene, Solvesso (registered trademark) 100 (available from Exxon Mobil Corporation) and Solvesso (registered trademark) 150 (available from Exxon Mobil Corporation); aliphatic hydrocarbons such as hexane, heptane and octane; esters such as ethyl acetate and butyl acetate; and the like. Such a solvent enables a solid content in the insulating layer-forming composition to be adjusted.

The lower limit of the solid content concentration of the insulating layer-forming composition is preferably 20% by mass and more preferably 40% by mass. Meanwhile, the upper limit of the solid content concentration of the insulating layer-forming composition is preferably 80% by mass and more preferably 70% by mass. When the solid content concentration is less than the lower limit, i.e., the content of the solvent is too high, a large amount of the solvent is vaporized during heating and consequently, a convection current from the solvent vaporized is likely to be generated in the vicinity of the surface of the metal layer 1a, leading to deterioration of surface smoothness of the insulating layer 1b. To the contrary, when the solid content concentration is greater than the upper limit, application of the insulating layer-forming composition may be difficult.

Processes of application and heating (drying and baking) of the insulating layer-forming composition are not particularly limited and well-known processes may be employed as appropriate. The process of application is exemplified by a bar coating process, a roll coating process, a curtain flow coating process, a spraying process, a spray wringer process, and the like. Of these, the bar coating process, the roll coating process, and the spray wringer process are preferred in light of cost effectiveness and the like.

The lower limit of a heating temperature of the insulating layer-forming composition is preferably 190° C. and more preferably 200° C. Meanwhile, the upper limit of the heating temperature is preferably 250° C. and more preferably 240° C. When the heating temperature is less than the lower limit, strength of the insulating layer 1b may be insufficient. To the contrary, when the heating temperature is greater than the upper limit, a convection current from a vaporized organic solvent is evaporated in the vicinity of the surface of the metal plate due to inhibition of rapid vaporization of the solvent, and consequently a convection current from the solvent vaporized is likely to be generated in the vicinity of the surface of the metal layer 1a, leading to deterioration of surface smoothness of the insulating layer 1b. It is to be noted that the term “heating temperature” as referred to means a peak metal temperature (PMT).

It is to be noted that, as described above, the reaction layer 1c may be formed on the metal layer 1a prior to the application of the insulating layer-forming composition. The rust-preventive layer 1d may also be provided on the surface of the metal layer 1a.

In addition, in order to improve flatness, the organic electronic element-laminated face of the substrate 1 (surface of the insulating layer 1b) may be subjected to a polishing treatment. A process of polishing is exemplified by chemical-mechanical polishing (CMP), electrolytic polishing, mechanical polishing, and the like. Of these, in view of removal of fine irregularities, chemical electrolytic polishing is preferred in which, for example, silica, alumina, ceria, titania, zirconia, germania, or the like is used as an abrasive.

### (Organic Electronic Element Overlaying Step)

In this step, the organic electronic element 2 is overlaid on the organic electronic element-laminated face of the substrate 1. As a process of overlaying, a well-known process may be employed.

### EXAMPLES

Hereinafter, the embodiments of the present invention will be explained more specifically by way of Examples; however, the present invention is not limited thereto.

### Examples 1 to 4

To a solvent prepared by blending equal amounts of xylene (boiling point: 140° C.) and cyclohexanone (boiling point: 156° C.): 75 parts by mass, on a solid content basis, of polyester (“Vylon (registered trademark) 200” available from Toyobo Co., Ltd. (glass transition point Tg: 53° C., number average molecular weight Mn: 3,000)); and 25 parts by mass, on a solid content basis, of a melamine resin (“Super Beckamine (registered trademark) J-820-60” available from DIC Corporation) were added to obtain a paint A. It is to be noted that the amount of the mixed solvent of xylene and cyclohexanone was adjusted such that a total solid content of the polyester and the melamine resin was 58% by mass.

As the metal layer, an electrogalvanized metal plate (EG) having a thickness of 0.8 mm, with a plated amount of zinc on each face of 20 g/m² was provided. On one face of the metal plate, an insulating layer having an average thickness of 15 μm was formed by applying the paint A with a bar coater and then heating the metal plate for 2 min such that the peak metal temperature (PMT) was 220° C. to obtain a substrate.

Next, for Examples 2 to 4, the substrate was subjected to chemical mechanical polishing to planarize the surface of the insulating layer. Specifically, the substrate was held by a holder, with a substrate-holding adhesive pad attached thereto, of a polishing apparatus, and then set on a polishing pad installed on a surface plate of the polishing apparatus, with the insulating layer directed downward. Chemical mechanical polishing was carried out for 10 min by using particulate alumina (mean particle diameter: approx. 100 nm) as an abrasive, under conditions involving: pressure being 65 g/cm²; rotation distance per round being 1 m; and rotation speed of the substrate and the surface plate each being 50 rpm.

Polishing depth was 3 μm for Example 2, 6 μm for Example 3, and 9 μm for Example 4.

On each of the substrates obtained after the polishing (except for the substrate of Example 1 obtained after the formation of the insulating layer), the surface profile of a 10 μm square area was evaluated with an atomic force microscope (model name: SPI 4000) available from SII NanoTechnology Inc., and arithmetic average roughness Ra was calculated.

In addition, the surface profile was evaluated on a plurality of 10 μm square areas, a line roughness analysis was conducted with an interval of 2.45 nm, and a K value for each irregularity peak was calculated by the above equation (1). The number of peaks having the K value of less than or equal to −0.07 and the number of peaks having the K value of less than or equal to −0.05 are shown in Table 1.

Furthermore, resistance of the insulating layer was measured pursuant to JIS-K-7194 (1994). The measurement results are shown in Table 1.

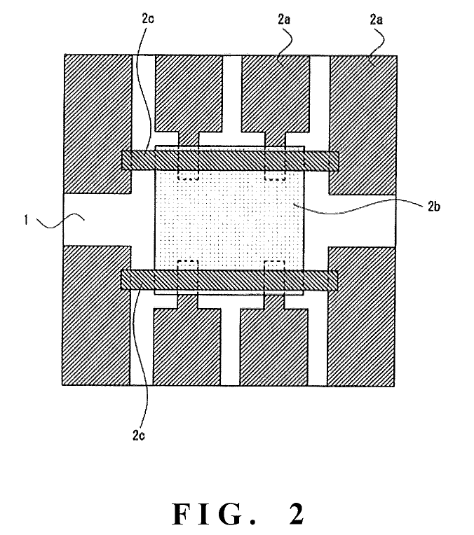

Subsequently, an organic EL element was overlaid on the surface of the substrate. The organic EL element was obtained by laminating: an ITO layer (average thickness: 50 nm); a PEDOT:PSS layer (average thickness: 60 nm); an NPD layer (average thickness: 80 nm); an Alq layer (average thickness: 50 nm); a LiF layer (0.8 nm); an AgMg layer (10 nm); and an IZO layer (100 nm), in this order. It is to be noted that the planar shape of the organic EL element was 2 mm square as shown in FIG. 2, and four of such organic EL elements were overlaid on a 30-mm square substrate. Furthermore, a transparent sealing glass was overlaid on the surface of the organic EL elements.

Specific conditions for overlaying the organic EL element were as follows. First, the substrate and the sealing glass were washed in a clean booth (Class 100) in a clean room (Class 1,000). As a washing agent, an organic solvent (EL grade), an organic alkali solution (EL grade), and ultra pure water (18 MΩ, TOC: less than or equal to 10 ppb) were used. As a washing apparatus, an ultrasonic washing apparatus (40 kHz and 950 kHz), a UV ozone washing apparatus, and a vacuum desiccator were used. A washing procedure included wet washing (ultra pure water, the organic alkali solution, and a combination of the organic solvent with the ultrasonic washing apparatus), drying (vacuum desiccation), and dry washing (UV ozone washing apparatus) carried out in this order.

After the washing of the substrate, each of the aforementioned layers was vapor-deposited in a vacuum of 1 to 2×10⁴ Pa and at a vapor deposition rate of 1 to 2 Å/s (0.01 Å/s for dopant, 0.1 Å/s for LiF) to overlay the organic EL elements.

After the overlaying of the organic EL elements, the sealing glass was overlaid thereon by: bonding the sealing glass to the organic EL elements in a glove box (H₂O and O₂ concentrations: less than 10 ppm); taking out from the glove box; irradiating with UV light; and, as a heat treatment, leaving to stand in a thermoregulated bath at 80° C. for 3 hrs. It is to be noted that, a 10-mm cube getter available from DYNIC CORPORATION was used as a getter, and a UV curable epoxy resin available from ThreeBond Co., Ltd. was used as a sealant.

In the organic electronic device thus obtained, the organic EL elements were made to emit light, the number of elements having emitted light was counted, and the organic electronic devices with two or more elements having emitted light were evaluated as acceptable. The evaluation results are shown in Table 1.

### Comparative Examples 1 and 2, and Examples 5 to 6

To a solvent prepared by blending equal amounts of xylene (boiling point: 140° C.) and cyclohexanone (boiling point: 156° C.): 21.75 parts by mass, on a solid content basis, of polyester (“Vylon (registered trademark) 200” available from Toyobo Co., Ltd. (Tg: 53° C., Mn: 3,000)); 7.25 parts by mass, on a solid content basis, of a melamine resin (“Super Beckamine (registered trademark) J-820-60” available from DIC Corporation); and 29.00 parts by mass, on a solid content basis, of titanium oxide particles (Tipaque (registered trademark) CR-50 (mean particle diameter: 0.25 μm) available from Ishihara Sangyo Kaisha, Ltd.) were added to obtain a paint B. The amount of the mixed solvent of xylene and cyclohexanone was adjusted such that a total solid content of the polyester, the melamine resin and the titanium oxide particles was 58% by mass.

Organic electronic devices were produced, and the aforementioned parameters were measured and evaluated similarly to Examples 1 to 4, except that an insulating layer having an average thickness of 25 μm was formed by using the paint B instead of the paint A and then heating for 2 min such that the peak metal temperature (PMT) was 220° C. The evaluation results are shown in Table 1.

### Comparative Example 3 and Examples 7, 8, 9

To a solvent prepared by blending equal amounts of xylene (boiling point: 140° C.) and cyclohexanone (boiling point: 156° C.): 26.1 parts by mass, on a solid content basis, of polyester (“Vylon (registered trademark) 200” available from Toyobo Co., Ltd. (Tg: 53° C., Mn: 3,000)); 8.7 parts by mass, on a solid content basis, of a melamine resin (“Super Beckamine (registered trademark) J-820-60” available from DIC Corporation); and 23.2 parts by mass, on a solid content basis, of titanium oxide particles (Tipaque (registered trademark) CR-50 (mean particle diameter: 0.25 μm) available from Ishihara Sangyo Kaisha, Ltd.) were added to obtain a paint C. The amount of the mixed solvent of xylene and cyclohexanone was adjusted such that a total solid content of the polyester resin, the melamine resin and the titanium oxide particles was 58% by mass.

Organic electronic devices were produced, and the aforementioned parameters were measured and the evaluated similarly to Examples 1 to 4, except that an insulating layer having an average thickness of 17 μm was formed by using the paint C instead of the paint A and then heating for 2 min such that the peak metal temperature (PMT) was 220° C. The evaluation results are shown in Table 1.

TABLE 1

| | | | | | | | | Organic |
|---|---|---|---|---|---|---|---|---|
| | | | | | | | | electronic |
| | | | | | | | | device |
| | | | | Substrate | | | | Number of |
| | Insulating layer | | | | Arithmetic | | | light- |
| | | Average | | Polishing | average | Number of | Number of | emitting |
| | | thickness | Resistance | depth | roughness | peaks K ≤−0.07 | peaks K ≤−0.05 | elements |
| | Paint | μm | Ωcm | μm | nm | — | — | — |
| Example 1 | A | 15 | 10¹⁴ | 0 | 2.6 | 0 | 1 | 3 |
| Example 2 | A | 15 | 10¹⁴ | 3 | 1.8 | 0 | 0 | 4 |
| Example 3 | A | 15 | 10¹⁴ | 6 | 1.2 | 0 | 1 | 4 |
| Example 4 | A | 15 | 10¹⁴ | 9 | 1.4 | 0 | 2 | 4 |
| Comparative | B | 25 | 10¹⁴ | 0 | 15.0 | 2 | 8 | 0 |
| Example 1 | | | | | | | | |
| Comparative | B | 25 | 10¹⁴ | 3 | 2.9 | 1 | 6 | 1 |
| Example 2 | | | | | | | | |
| Example 5 | B | 25 | 10¹⁴ | 6 | 6.4 | 0 | 0 | 4 |
| Example 6 | B | 25 | 10¹⁴ | 9 | 8.1 | 0 | 3 | 4 |
| Comparative | C | 17 | 10¹⁴ | 0 | 23.1 | 1 | 7 | 1 |
| Example 3 | | | | | | | | |
| Example 7 | C | 17 | 10¹⁴ | 3 | 5.9 | 0 | 6 | 2 |
| Example 8 | C | 17 | 10¹⁴ | 6 | 9.2 | 0 | 5 | 4 |
| Example 9 | C | 17 | 10¹⁴ | 9 | 12.0 | 0 | 0 | 4 |

As shown in Table 1, in all of Examples 1 to 9 and Comparative Examples 1 to 3, the arithmetic average roughness of the surface of the substrates was less than or equal to 25 nm. However, in Comparative Examples 1 to 3, the number of elements found to have emitted light was less than 2, indicating that short-circuit was likely to occur. In particular, in Comparative Example 2, the number of elements having emitted light was 1 in spite of the arithmetic average roughness being as small as 2.9 nm. In other words, it is proven that merely specifying the surface roughness of the surface of the substrate is not enough for inhibition of the short-circuit. On the other hand, in Examples 1 to 9, the number of peaks having the K value of less than or equal to −0.07 was 0, and the number of elements having emitted light was greater than or equal to 2. It is thus proven that getting rid of peaks having the K value of less than or equal to −0.07 enables inhibition of the short-circuit.

Furthermore, among Examples 1 to 9, in Examples 2, 5 and 9, the number of peaks having the K value of less than or equal to −0.05 was 0, and the number of elements having emitted light was 4, indicating that no short-circuit occurred. It is thus proven that getting rid of peaks having the K value of less than or equal to −0.05 enables more reliable inhibition of the short-circuit.

The present invention has been described in detail and with reference to specific embodiments; however, it would be apparent to one of ordinary skill in the art that various changes and modifications can be made without departing from the spirit and scope of the present invention.

The present application claims priority to Japanese Patent Application No. 2015-109226, filed on May 28, 2015. The contents of the application are incorporated herein by reference in their entirety.

### INDUSTRIAL APPLICABILITY

As explained in the foregoing, the organic electronic device and the substrate for an organic electronic device according to embodiments of the present invention are superior in production yield, due to inhibition of occurrence of short-circuit of the element, and therefore can be suitably used for various applications.

### EXPLANATION OF THE REFERENCE SYMBOLS

1 Substrate
1a Metal layer
1b Insulating layer
1c Reaction layer
1d Rust-preventive layer
2 Organic electronic element
2a ITO layer
2b PEDOT:PSS layer/NPD layer/Alq layer
2c LiF layer/AgMg layer

1. An organic electronic device comprising a substrate and an organic electronic element overlaid on one face of the substrate, wherein:
the substrate comprises a metal layer and an insulating layer overlaid on at least one face side of the metal layer; and
the one face of the substrate does not have an irregularity peak having a K value of less than or equal to −0.07 as calculated by equation (1):
K=[f(x+dx)−2f(x)+f(x−dx)]/dx² (1)
wherein in the equation (1):
x represents an irregularity peak position when a line roughness analysis is conducted on a 10 μm square on the one face of the substrate with an interval of 2.45 nm;
f(x) represents a surface irregularity height (nm) at x; and
dx represents an infinitesimal change in x.

2. The organic electronic device according to claim 1, wherein the insulating layer comprises a synthetic resin as a principal component.

3. The organic electronic device according to claim 2, wherein the insulating layer comprises a pigment.

4. The organic electronic device according to claim 3, wherein:
the pigment is an inorganic pigment;
a mean particle diameter of the pigment is less than or equal to 300 nm; and
a content of the pigment in the insulating layer is less than or equal to 50% by mass.

5. The organic electronic device according to claim 2, wherein the synthetic resin is a thermosetting resin.

6. The organic electronic device according to claim 3, wherein the synthetic resin is a thermosetting resin.

7. The organic electronic device according to claim 4, wherein the synthetic resin is a thermosetting resin.

8. The organic electronic device according to claim 2, wherein the synthetic resin is a polyester and the insulating layer comprises a thermosetting agent.

9. The organic electronic device according to claim 3, wherein the synthetic resin is a polyester and the insulating layer comprises a thermosetting agent.

10. The organic electronic device according to claim 4, wherein the synthetic resin is a polyester and the insulating layer comprises a thermosetting agent.

11. The organic electronic device according to claim 1, wherein the metal layer comprises iron, titanium, or an alloy thereof as a principal component.

12. The organic electronic device according to claim 1, wherein the organic electronic device is used for an organic EL lighting system or an organic solar cell.

13. A substrate for an organic electronic device comprising the substrate and an organic electronic element overlaid on one face of the substrate,
the substrate comprising a metal layer and an insulating layer overlaid on at least one face side of the metal layer,
wherein the one face of the substrate does not have an irregularity peak having a K value of less than or equal to −0.07 as calculated by equation (1):
K=[f(x+dx)−2f(x)+f(x−dx)]/dx² (1)
wherein in the equation (1):
x represents an irregularity peak position when a line roughness analysis is conducted on a 10 μm square on the one face of the substrate with an interval of 2.45 nm;
f(x) represents a surface irregularity height (nm) at x; and
dx represents an infinitesimal change in x.
